(19) United States
(12) Patent Application Publication
(10) Pub. No.: US 2014/0001553 A1
(43) Pub. Date: Jan. 2, 2014

(54) METHOD AND SYSTEM FOR IMPROVED ANALOG PERFORMANCE IN SUB-100 NANOMETER CMOS TRANSISTORS

(71) Applicant: Kimihiko Imura, San Diego, CA (US)

(72) Inventor: Kimihiko Imura, San Diego, CA (US)

(21) Appl. No.: 13/926,603

(22) Filed: Jun. 25, 2013

Related U.S. Application Data
(60) Provisional application No. 61/666,400, filed on Jun. 29, 2012.

(51) Int. Cl. H01L 27/092; H01L 21/8238

(52) U.S. Cl. CPC H01L 27/092; H01L 21/823807
USPC 257/344; 438/217

(57) ABSTRACT

Methods and systems for improved analog performance of core CMOS transistors may comprise a semiconductor die comprising both input/output (I/O) complementary metal oxide semiconductor (CMOS) transistors and core CMOS transistors. A doping profile of a subset of the core CMOS transistors may comprise lightly-doped drain and pocket implant layers between source and drain layers below a gate insulator, and a doping profile of another subset of the core CMOS transistors may be constant between source and drain layer. The core CMOS devices may comprise sub-100 nanometer gate lengths. An output resistance of the second subset of the core CMOS transistors may be increased by the constant doping profile between the source and drain layers. The second subset of the core CMOS transistors may be operable to amplify analog signals. The first subset of the core CMOS transistors may be operable to process digital signals.

### CROSS-REFERENCE TO RELATED APPLICATIONS/INCORPORATION BY REFERENCE

This application makes reference to and claims priority to U.S. Provisional Application Ser. No. 61/666,400 filed on Jun. 29, 2012. The above identified application is hereby incorporated herein by reference in its entirety.

### FIELD OF THE INVENTION

Certain embodiments of the invention relate to semiconductor devices. More specifically, certain embodiments of the invention relate to a method and system for improved analog performance in sub-100 nanometer CMOS transistors.

### BACKGROUND OF THE INVENTION

Complementary metal oxide semiconductor (CMOS) transistors are ubiquitous in today's electronics devices. As more devices are being integrated onto CMOS chips, gate lengths have decreased to less than 100 nanometers, leading to the incorporation of pocket, or halo, structures under lightly doped drains to mitigate short channel effects, such as threshold voltage reduction.

Further limitations and disadvantages of conventional and traditional approaches will become apparent to one of skill in the art, through comparison of such systems with the present invention as set forth in the remainder of the present application with reference to the drawings.

### BRIEF SUMMARY OF THE INVENTION

A system and/or method for improved analog performance in sub-100 nanometer CMOS transistors substantially as shown in and/or described in connection with at least one of the figures, as set forth more completely in the claims.

Various advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a diagram illustrating a conventional CMOS transistor, in accordance with an embodiment of the invention.

FIG. 2 is a diagram of an exemplary CMOS transistor with no lightly doped drain or pocket implants, in accordance with an embodiment of the invention.

FIG. 3 is a diagram illustrating an exemplary core CMOS transistor with a input/output device lightly-doped drain implant, in accordance with an embodiment of the invention.

FIG. 4 is a diagram illustrating core and input/output CMOS transistors in a chip, in accordance with an embodiment of the invention.

### DETAILED DESCRIPTION OF THE INVENTION

Certain aspects of the invention may be found in a method and system for improved analog performance in sub-100 nanometer CMOS transistors. Exemplary aspects of the invention may comprise a semiconductor die comprising both input/output (I/O) complementary metal oxide semiconductor (CMOS) transistors and core CMOS transistors. A doping profile of a first subset of the core CMOS transistors may comprise lightly-doped drain and pocket implant layers between source and drain layers below a gate insulator of the first subset of the core CMOS transistors, and a doping profile of a second subset of the core CMOS transistors may be constant between source and drain layers directly below a gate insulator of a second subset of the core CMOS transistors. The core CMOS devices may comprise sub-100 nanometer gate lengths. The I/O CMOS transistors may comprise greater than 100 nanometer gate lengths. An output resistance of the second subset of the core CMOS transistors may be increased by the constant doping profile between the source and drain layers. The core CMOS transistors may comprise a gate with adjacent spacer layers on the gate insulator. The second subset of the core CMOS transistors may be operable to amplify analog signals. The I/O CMOS transistors may be operable to communicate signals into and out of the CMOS chip. The first subset of the core CMOS transistors may be operable to process digital signals.

As utilized herein, “and/or” means any one or more of the items in the list joined by “and/or”. As an example, “x and/or y” means any element of the three-element set {(x), (y), (x, y)}. As another example, “x, y, and/or z” means any element of the seven-element set {(x), (y), (z), (x, y), (x, z), (y, z), (x, y, z)}. As utilized herein, the terms “block” and “module” refer to functions than can be implemented in hardware, software, firmware, or any combination of one or more thereof. As utilized herein, the term “exemplary” means serving as a non-limiting example, instance, or illustration. As utilized herein, the term “e.g.,” introduces a list of one or more non-limiting examples, instances, or illustrations.

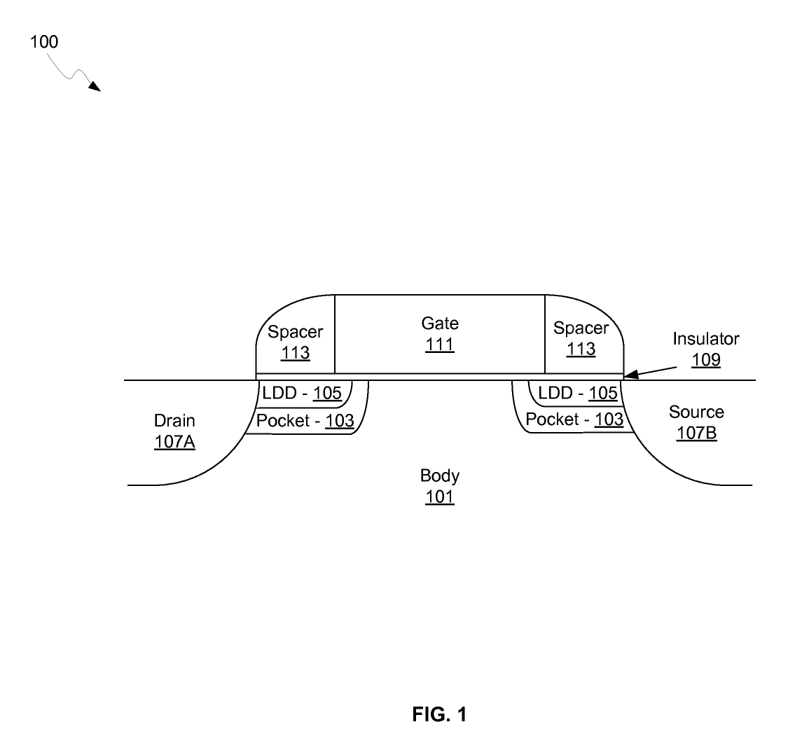

FIG. 1 is a diagram illustrating a conventional CMOS transistor, in accordance with an embodiment of the invention. Referring to FIG. 1, there is shown a transistor 100 comprising a bulk-like layer, or body layer 101, pocket implants 103, lightly-doped drains 105, drain 107A and source 107B diffusion layers, a gate insulator 109, a gate 111, and spacer layers 113. The body layer 101 may comprise the substrate material, or may comprise an n-well or p-well, for example, depending on whether it is an p-channel device or a n-channel device.

For CMOS transistors with gate lengths less than 100 nm, lightly-doped drains and pocket implants are utilized to mitigate short channel effects. These effects can include drain-induced barrier lowering and punchthrough, carrier velocity saturation, and the generation of hot electrons. In core CMOS transistors, lightly-doped drain implants, the lightly-doped drains 105, are used to mitigate the effect that the high electric field from the drain voltage may have on the short channel.

In addition, the pocket implants 103 are doped with the same type to that of the body layer 101, thereby forming stronger p-n junctions at the drain and source than with without the pockets. These p-n junctions mitigate drain-induced barrier lowering at the source side that is enhanced when the gate length is shortened below 100 nm. For these reasons, sub-100 nm gate length CMOS transistors require lightly-doped drain implants and pocket implants.

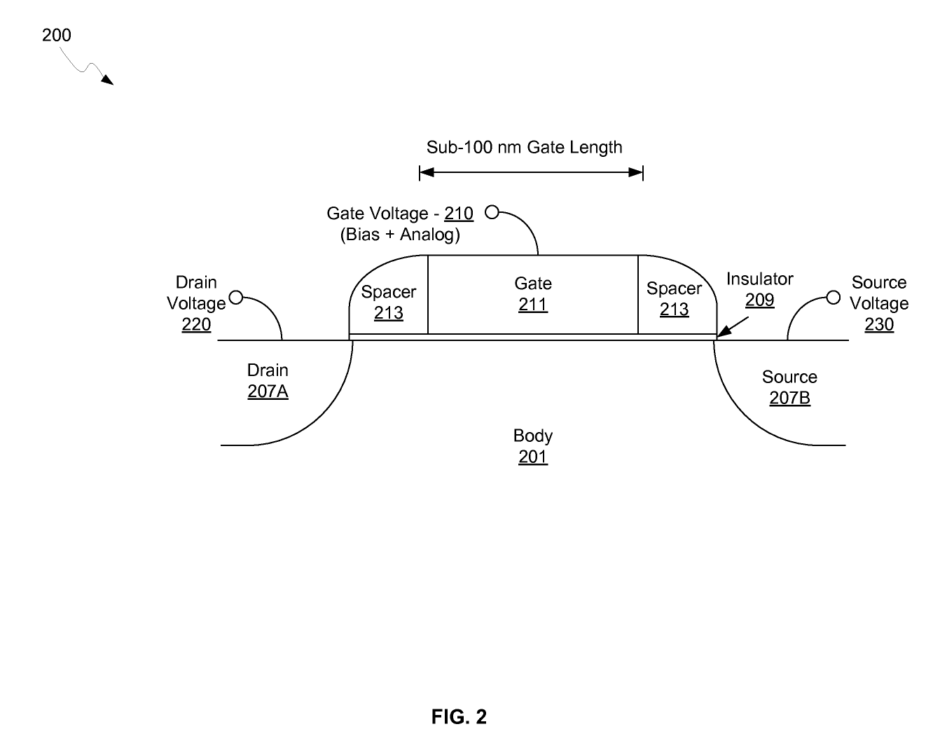

FIG. 2 is a diagram of an exemplary CMOS transistor with no lightly doped drain or pocket implants, in accordance with an embodiment of the invention. Referring to FIG. 2, there is shown a CMOS transistor 200 comprising a body layer 201 (e.g. substrate or well), a drain 207A, a source 207B, a gate insulator 209, a gate 211, and spacer layers 213. It should be noted that for illustration purposes the relative thicknesses of the various layers are not shown to scale.

The drain 207A and source 207B may comprise the source and drain terminals for the CMOS transistor 200 and may be created by a salicide process with the spacer layers 213 as a mask for the diffusion process.

The spacer layers 213 may comprise a dielectric, such as an oxide or nitride material, which provides isolation for the gate 211 and also acts as a mask for the salicide process.

The gate 211 may comprise polysilicon or metal, for example, and may provide the gate terminal for the CMOS transistor 200. The gate 211 is on top of the gate insulator 209, which provides electrical isolation between the gate and the body layer 201. The gate insulator 209 may comprise silicon dioxide or other insulating material on the body layer 201.

When an above-threshold, in magnitude, voltage is applied to the gate 211, and a voltage is applied between the drain and source layers 207A and 207B, current may flow. Two typical applications for CMOS transistors are digital switching or analog signal amplification. In a switching application, the gate voltage is changed from low to high, and vice versa, to allow or restrict drain to source current flow. A biasing voltage applied to the gate 211, the gate voltage 210, above a threshold voltage creates a channel for current to flow between the drain 207A and source 207B when a drain-source voltage is applied.

In an analog amplification application, an above-threshold gate voltage may be applied in conjunction with a drain-source voltage to bias the transistor in a linear range, such that a small signal AC signal applied to the gate, gate voltage 210, will be amplified via the resulting modulation of the drain-source current.

Conventional sub-100 nm CMOS transistors utilize both pocket and LDD implants to mitigate short channel effects. In an exemplary scenario, the CMOS transistor 200 may be configured with neither the lightly-doped drain nor the pocket implant. Capacitive coupling in the spacer layers 213 between the gate 211 and the body layer 201 under the spacer layers 213 may generate inversion carriers in the body below the spacer. The CMOS transistor 200 without LDD and pocket implants may result in higher output impedance as well as better transistor matching across a die, since the pocket implants degrade device matching and reduce output resistance.

In an example scenario, the CMOS transistor 200 may comprise a core CMOS device, as opposed to a peripheral input/output (I/O) device. Core CMOS devices may operate at lower voltages of ˜1.0V and at higher speeds with shorter gate lengths (e.g., sub-100 nm), while I/O devices may operate in a higher voltage range, 1.8-3.3 V, but lower speeds with longer gate lengths, typically. Exemplary I/O devices may be utilized for analog implementations, such as operational amplifiers. However, the CMOS transistor 200, a core device, may be utilized for analog applications because of the higher output resistance. In this manner, core CMOS devices may be utilized for analog applications.

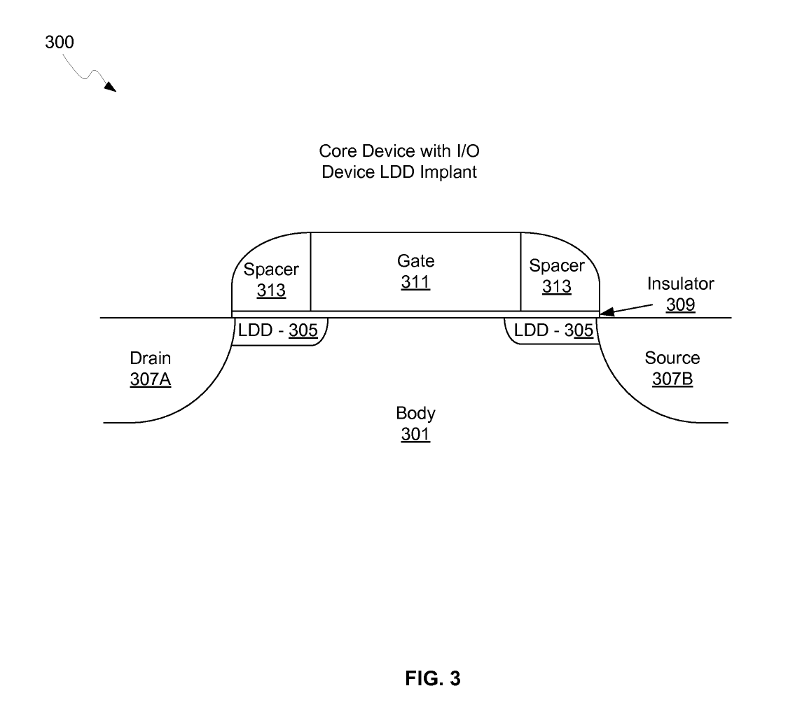

FIG. 3 is a diagram illustrating an exemplary core CMOS transistor with a input/output device lightly-doped drain implant, in accordance with an embodiment of the invention. Referring to FIG. 3, there is shown a CMOS transistor 300 comprising spacer layers 313, a gate 311, a gate insulator 309, a body layer 301, drain and source layers 307A and 307B, and I/O device LDD implants 305.

The CMOS transistor 300 may comprise a core device, as opposed to an I/O device, with gate lengths down to the process minimum. An I/O device LDD implant may be incorporated with the core CMOS structure. This exemplary scenario may result in improved device matching and output resistance while still mitigating the higher fields from the higher voltages utilized.

The exemplary embodiments described may enable configurable device performance without any changes to the CMOS process other than the utilization of different existing masks. For example, the LDD and pocket implants may still be performed on the wafers but not implanted in the embodiments described with respect to FIGS. 2 and 3 due to masking.

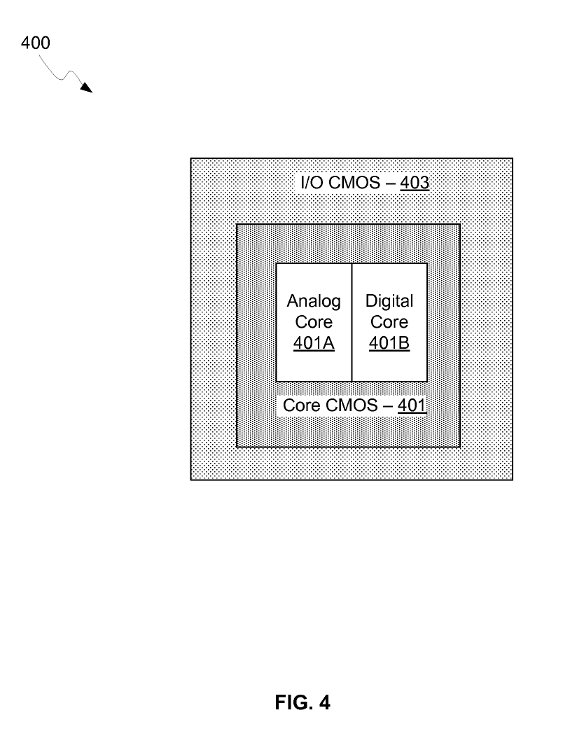

FIG. 4 is a diagram illustrating core and input/output CMOS transistors in a chip, in accordance with an embodiment of the invention. Referring to FIG. 4, there is shown a CMOS chip 400 comprising analog core CMOS transistors 401A, digital core CMOS transistors 401B, and I/O CMOS transistors 403. Core CMOS transistors may typically be used for high speed digital applications and as such have the minimum gate lengths, 40 nanometers in the case of 40 nanometer technology, for example, compared to I/O CMOS transistors that operate at higher voltage and have longer gate lengths, longer than 100 nanometers, for example. I/O CMOS transistors may be utilized to communicate signals into and out of the CMOS chip 400, and may be used for analog applications.

Core CMOS transistors in the sub-100 nanometer gate length range utilize lightly-doped drain and pocket implant to mitigate short-channel effects. However, in an example scenario, the analog core CMOS transistors 401A may be configured with no lightly-doped drain or pocket diffusions to improve analog performance due to increased output resistance and improved uniformity across the CMOS chip 400.

Thus, the CMOS chip 400 may still be processed through the LDD and pocket implants, but masked in the analog core CMOS transistors 401A, while the digital core CMOS transistors 401B do receive lightly-doped drain and pocket implants. In this manner, a constant doping profile is obtained directly below the gate oxide in the analog CMOS transistors, as shown in FIG. 2, and as opposed to the digital core transistors that include lightly-doped drain regions and pockets, as shown in FIG. 1.

The improved analog performance may enable the sub-100 nanometer core transistors to be used in high performance analog applications, as opposed to the exclusive use of I/O CMOS transistors. Furthermore, the digital core CMOS transistors 401B may be utilized to process digital signals, comprising a processor, for example. In this manner, both digital and analog optimized CMOS transistors may be fabricated in the same process, thereby greatly reducing costs and chip areas required in mixed-signal systems.

In an embodiment of the invention, a method and system may comprise a semiconductor die 400 comprising both input/output (I/O) complementary metal oxide semiconductor (CMOS) transistors 403 and core CMOS transistors 401A and 401B. A doping profile of a first subset 401B of the core CMOS transistors may comprise lightly-doped drain 105, 305 and pocket implant 103 layers between source 107B and drain layers 107A below a gate insulator 109 of the first subset 401B of the core CMOS transistors 401, and a doping profile of a second subset 401A of the core CMOS transistors 401 may be constant between source 207B and drain layers 207A directly below a gate insulator 209 of the second subset 401B of the core CMOS transistors 401.

The core CMOS devices 200, 401 may comprise sub-100 nanometer gate lengths. The I/O CMOS transistors 403 may comprise greater than 100 nanometer gate lengths. An output resistance of the second subset 401A of the core CMOS transistors 401 may be increased by the constant doping profile between the source 207B and drain layers 207A.

The core CMOS transistors may comprise a gate 111, 211, 311 with adjacent spacer layers 113, 213, 313 on the gate insulator 109, 209, 309. The second subset of the core CMOS transistors may be operable to amplify analog signals. The I/O CMOS transistors 403 may be operable to communicate signals into and out of the CMOS chip 400. The first subset 401B of the core CMOS transistors 401 may be operable to process digital signals.

Other embodiments of the invention may provide a non-transitory computer readable medium and/or storage medium, and/or a non-transitory machine readable medium and/or storage medium, having stored thereon, a machine code and/or a computer program having at least one code section executable by a machine and/or a computer, thereby causing the machine and/or computer to perform the steps as described herein for improving analog performance in sub-100 nm CMOS transistors.

Accordingly, aspects of the invention may be realized in hardware, software, firmware or a combination thereof. The invention may be realized in a centralized fashion in at least one computer system or in a distributed fashion where different elements are spread across several interconnected computer systems. Any kind of computer system or other apparatus adapted for carrying out the methods described herein is suited. A typical combination of hardware, software and firmware may be a general-purpose computer system with a computer program that, when being loaded and executed, controls the computer system such that it carries out the methods described herein.

One embodiment of the present invention may be implemented as a board level product, as a single chip, application specific integrated circuit (ASIC), or with varying levels integrated on a single chip with other portions of the system as separate components. The degree of integration of the system will primarily be determined by speed and cost considerations. Because of the sophisticated nature of modern processors, it is possible to utilize a commercially available processor, which may be implemented external to an ASIC implementation of the present system. Alternatively, if the processor is available as an ASIC core or logic block, then the commercially available processor may be implemented as part of an ASIC device with various functions implemented as firmware.

The present invention may also be embedded in a computer program product, which comprises all the features enabling the implementation of the methods described herein, and which when loaded in a computer system is able to carry out these methods. Computer program in the present context may mean, for example, any expression, in any language, code or notation, of a set of instructions intended to cause a system having an information processing capability to perform a particular function either directly or after either or both of the following: a) conversion to another language, code or notation; b) reproduction in a different material form. However, other meanings of computer program within the understanding of those skilled in the art are also contemplated by the present invention.

While the invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiments disclosed, but that the present invention will include all embodiments falling within the scope of the appended claims.

What is claimed is:

1. A method for a semiconductor device, the method comprising:
fabricating a semiconductor die comprising input/output (I/O) complementary metal oxide semiconductor (CMOS) transistors and core CMOS transistors;
configuring a doping profile to comprise lightly-doped drain and pocket implant layers between source and drain layers and below a gate insulator of a first subset of the core CMOS transistors; and
configuring a doping profile to be constant between source and drain layers directly below a gate insulator of a second subset of the core CMOS transistors.

2. The method according to claim 1, wherein the core CMOS transistors comprise sub-100 nanometer gate lengths.

3. The method according to claim 1, comprising placing a gate with adjacent spacer layers on the gate insulator of the core transistors.

4. The method according to claim 1, comprising increasing an output resistance of the second subset of the core CMOS transistors by providing the constant doping profile between the source and drain layers.

5. A semiconductor device comprising:
a semiconductor die comprising both input/output (I/O) complementary metal oxide semiconductor (CMOS) transistors and core CMOS transistors,
a doping profile of a first subset of the core CMOS transistors that comprises lightly-doped drain and pocket implant layers between source and drain layers below a gate insulator of the first subset of the core CMOS transistors; and
a doping profile of a second subset of the core CMOS transistors that is constant between source and drain layers directly below a gate insulator of the second subset of the core CMOS transistors.

6. The system according to claim 5, wherein the core CMOS devices comprise sub-100 nanometer gate lengths.

7. The system according to claim 5, wherein the I/O CMOS transistors comprise greater than 100 nanometer gate lengths.

8. The system according to claim 5, wherein an output resistance of the second subset of the core CMOS transistors is increased by the constant doping profile between the source and drain layers.

9. The system according to claim 5, wherein the core CMOS transistors comprise a gate with adjacent spacer layers on the gate insulator.

10. The system according to claim 5, wherein the second subset of the core CMOS transistors is operable to amplify analog signals.

11. The system according to claim 5, wherein the I/O CMOS transistors are operable to communicate signals into and out of the CMOS chip.

12. The system according to claim 5, wherein the first subset of the core CMOS transistors are operable to process digital signals.

13. A semiconductor device comprising:
a semiconductor die comprising both input/output (I/O) complementary metal oxide semiconductor (CMOS) transistors and core CMOS transistors,
a doping profile of a first subset of the core CMOS transistors that comprises lightly-doped drain and pocket implant layers between source and drain layers below a gate insulator of the first subset of the core CMOS transistors; and
a doping profile of a second subset of the core CMOS transistors that is constant between lightly-doped drain layers at source and drain sides of the second subset of the core CMOS transistors.

14. The system according to claim 13, wherein the second subset of the core CMOS transistors comprise lightly-doped drain implant layers.

15. The system according to claim 13, wherein the core CMOS devices comprise sub-100 nanometer gate lengths.

16. The system according to claim 13, wherein the I/O CMOS transistors comprise greater than 100 nanometer gate lengths.

17. The system according to claim 13, wherein an output resistance of the second subset of the core CMOS transistors is increased by the constant doping profile between the source and drain layers.

18. The system according to claim 13, wherein the second subset of the core CMOS transistors is operable to amplify analog signals.

19. The system according to claim 13, wherein the I/O CMOS transistors are operable to communicate signals into and out of the CMOS chip.

20. The system according to claim 13, wherein the first subset of the core CMOS transistors are operable to process digital signals.
